(19) United States
(12) Patent Application Publication
(10) Pub. No.: US 2026/0251452 A1
(43) Pub. Date: Aug. 27, 2026

(54) METHOD AND DEVICE FOR PASSIVELY IDENTIFYING SYSTEM PARAMETERS OF A MICROELECTROMECHANICAL SYSTEM

(71) Applicant: Robert Bosch GmbH, Stuttgart (DE)

(72) Inventors: Wolfram Mayer, Harthausen (DE); Burkhard Kuhlmann, Reutlingen (DE); Thorsten Balslink, Kirchentellinsfurt (DE)

(21) Appl. No.: 19/534,018

(22) Filed: Feb. 9, 2026

(30) Foreign Application Priority Data
Feb. 21, 2025 (DE) 10 2025 106 643.4

(51) Int. Cl. G01C 19/5776; G01C 19/5712

(52) U.S. Cl. CPC G01C 19/5776; G01C 19/5712

(57) ABSTRACT

A method and a device for passively identifying system parameters of a microelectromechanical system. The method includes a plurality of steps, namely measuring a signal output by the microelectromechanical system excited by noise, determining a frequency response of the measured signal and identifying system parameters of the microelectromechanical system based on the frequency response of the measured signal.

### CROSS REFERENCE

The present application claims the benefit under 35 U.S.C. § 119 of Germany Patent Application No. DE 10 2025 106 643.4 filed on February 21, 2025, which is expressly incorporated herein by reference in its entirety.

### FIELD

The present disclosure relates to a method and a device for passively and continuously identifying system parameters of a microelectromechanical system, in particular of microelectromechanical sensors.

### BACKGROUND INFORMATION

MEMS stands for microelectromechanical systems in which microscopically small mechanical and electrical components are combined and integrated on a chip. A microelectromechanical system may include a microelectromechanical sensor, in particular a rotation rate sensor. The rotation rate sensor oscillates continuously in drive mode. A rotation applied to the sensor leads to a deflection of the detection mode due to the Coriolis force. The magnitude of the deflection is proportional to the applied rotation rate.

Open-loop describes a system concept in which no control loop is used for position control of the micromechanics in the detection. In an open-loop system, measuring is carried out directly by detecting the output signals without active feedback for controlling the oscillations. This method is simpler and less complex, but more sensitive to noise disturbances and temperature effects compared to closed-loop systems, which use feedback to improve mode stability.

The MEMS sensors produced in a batch process must be calibrated after production. In this calibration, deviations caused by process variation are compensated for individually for each sensor based on mathematical models. Following calibration, the sensors are, however, subject to certain disturbances, for example changes in temperature, humidity, mechanical stress (e.g. bending of the circuit board on which the sensor is soldered), aging effects, linear and rotational accelerations and/or vibrations, and mechanical shocks. The calibration of the sensors is then no longer optimal.

This influence causes a change in performance variables, such as, inter alia, offset and sensitivity, and should therefore be recalibrated with the best possible accuracy. Due to a lack of ability for controlled stimulation of the sensors in the field, an adaptation of the mathematical models used in calibration is usually difficult and not possible with sufficient accuracy. This aspect is amplified by the plurality of specific customer applications. Therefore, a goal of various compensation methods is to directly counteract a possible change in the performance variables. For this purpose, for example, an identified system parameter can be used as an input variable.

Conventional methods are based on active excitation of the system in order to execute subsequent system identification (inter alia, identification of the frequency split). An example of continuous frequency tracking is described in U.S. Patent No. US 11,754,397 B2, "Microelectromechanical System (MEMS) Gyroscope Sense Frequency Tracking."

System tracking is conventionally based on active excitation of the MEMS component along with simultaneous or subsequent measuring of the system response. Via system identification, system parameters, such as the frequency split and the quality factor, can then be determined. These system parameters can then be used in calibration and/or compensation to adapt mathematical models of the system accordingly.

However, one disadvantage of previous conventional methods is the need for active excitation of the system. The active excitation of an investigated electromechanical system must be carried out in such a way that, during ongoing operation, the useful signal of the electromechanical system is not impaired. For excitation of the system, it is necessary to provide additional signal sources and/or test-signal electrodes.

### SUMMARY

According to a first aspect, the present disclosure provides a method for passively identifying system parameters of a microelectromechanical system. According to example embodiment, the method comprises the following steps:

measuring a signal output by the microelectromechanical system excited by noise;

determining a frequency response of the measured signal; and

identifying system parameters of the microelectromechanical system based on the frequency response of the measured signal.

The method has an advantage that it is not necessary to provide additional signal sources and/or test-signal electrodes for excitation of the relevant microelectromechanical system. This simplifies the manufacturing process and saves space when integrating the microelectromechanical system.

In a possible example embodiment of the method according to the present disclosure for passively ascertaining system parameters of a microelectromechanical system, an amplitude frequency response of the measured signal is determined for certain frequencies or frequency ranges. In the case of these frequency ranges, these can be signal channels.

In a possible example embodiment of the method according to the present disclosure for passively ascertaining system parameters of a microelectromechanical system, the measured signal is sampled and filtered, and the frequency response of the signal is determined by a fast Fourier transform (FFT) of the filtered signal. The fast Fourier transform is an efficient algorithm for calculating the discrete Fourier transform. The FFT converts the signal from the time domain to the frequency domain. The FFT algorithm receives a sequence of discrete values (e.g. measured values of a signal) for determining the frequency response.

The method according to the present disclosure is based on measuring the unfiltered and uncompensated for signal of the microelectromechanical system excited by noise, for example a microelectromechanical rotation rate sensor. By calculating the Fourier transform of the noise signal, the noise signal can be decomposed into the contained frequency components and represented as a transfer function of the system. From this frequency response, system parameters of the microelectromechanical system, in particular the frequency split and the quality factor of a MEMS rotation rate sensor, can be identified.

In a possible embodiment of the method according to the present disclosure for passively ascertaining system parameters of a microelectromechanical system, the system parameters of the microelectromechanical system are identified based on the frequency response of the measured signal by means of curve fitting, three-point fitting, Kalman filtering or by a neural network.

In a possible embodiment of the method according to the present disclosure for passively ascertaining system parameters of a microelectromechanical system, the identified system parameters of the microelectromechanical system are stored. This is preferably carried out by storing the data in an integrated storage unit of the microelectromechanical system.

In a possible example embodiment of the method according to the present disclosure for passively ascertaining system parameters of a microelectromechanical system, the microelectromechanical system is continuously monitored on the basis of the identified system parameters. The method can be executed in the background without affecting the ongoing operation of the microelectromechanical system.

In a possible example embodiment of the method according to the present disclosure for passively ascertaining system parameters of a microelectromechanical system, a compensation mechanism is executed on the basis of the identified system parameters. This can also be executed after delivery based on the system parameters stored in a memory unit of the delivered end product.

In a possible example embodiment of the method according to the present disclosure for passively ascertaining system parameters of a micromechanical system, the microelectromechanical system comprises a micromechanical sensor that outputs a signal and whose system parameters are identified.

In a possible example embodiment of the method according to the present disclosure for passively ascertaining system parameters of a microelectromechanical system, the microelectromechanical sensor comprises a rotation rate sensor that outputs a signal and whose system parameters are identified. Rotation rate sensors are widely used and can be used in a plurality of assistance systems.

In a possible example embodiment of the method according to the present disclosure for passively ascertaining system parameters of a micromechanical system, the system parameters of the rotation rate sensor comprise a frequency split of the rotation rate sensor and/or a quality factor of the rotation rate sensor.

The method according to the present disclosure is capable of identifying system parameters in mode-split MEMS rotation rate sensors (frequency split, quality factor, etc.).

According to a second aspect, the present disclosure further provides a device for passively identifying system parameters of a microelectromechanical system, the device comprising:

a measurement unit which is configured to measure a signal output by the microelectromechanical system excited by noise;

a frequency response determination unit which is configured to determine a frequency response of the signal measured by the measurement unit; and

a system parameter identification unit which is configured to identify system parameters of the micromechanical system based on the frequency response of the measured signal determined by the frequency response determination unit.

The present disclosure further provides a microelectromechanical system comprising a device for passively identifying system parameters of the micromechanical system according to the second aspect of the present disclosure.

In a possible example embodiment of the microelectromechanical system, the microelectromechanical system comprises a rotation rate sensor.

In a possible example embodiment of the microelectromechanical system, the microelectromechanical system comprises an acceleration sensor.

Further possible example embodiments, developments and implementations of the present disclosure also include combinations not explicitly mentioned of features of the present disclosure described above or in the following relating to the exemplary embodiments. In particular, a person skilled in the art will also add individual aspects as improvements or additions to the respective configurations and additional forms, to the extent that such additions are meaningful, and can combine these arbitrarily with one another to the basic form of the present invention.

The present disclosure is explained in more detail below on the basis of the exemplary embodiments indicated in the schematic figures of the figures.

### BRIEF DESCRIPTION OF THE DRAWINGS

FIG. 1 is a schematic flow chart for representing a possible embodiment of the method according to the present disclosure for passively ascertaining system parameters of a micromechanical system.

FIG. 2 is a schematic block diagram for representing a possible embodiment of a device according to the present disclosure for passively identifying system parameters of a micromechanical system.

FIG. 3 is a diagram for explaining the method according to the present disclosure and the device according to the present disclosure.

FIG. 4 is a further diagram for explaining the method according to the present disclosure and the device according to the present disclosure.

FIG. 5 is a block circuit diagram for representing a possible embodiment of a microelectromechanical system according to the present disclosure, the system comprising a device according to the present disclosure integrated therein for passively identifying system parameters of the microelectromechanical system.

FIG. 6 is a block circuit diagram for representing a possible embodiment of a microelectromechanical system comprising a device connected thereto for passively identifying system parameters of the microelectromechanical system, according to the present disclosure.

The accompanying figures are intended to impart further understanding of the example embodiments of the present disclosure. They illustrate embodiments and, in connection with the description, serve to explain principles and concepts of the present disclosure. Other embodiments and many of the mentioned advantages are apparent from the present disclosure. The elements of the figures are not necessarily shown to scale relative to one another.

### DETAILED DESCRIPTION OF EXAMPLE EMBODIMENTS

In the figures, identical, functionally identical and identically acting elements, features and components are in each case provided with the same reference signs, to the extent that nothing else is stated.

In the following explanations, identification of the frequency split is addressed; equivalently, identification of the quality factor, etc. can also be carried out. Furthermore, the principle is not limited only to the useful mode of detection, but rather further, higher modes can also be detected and evaluated.

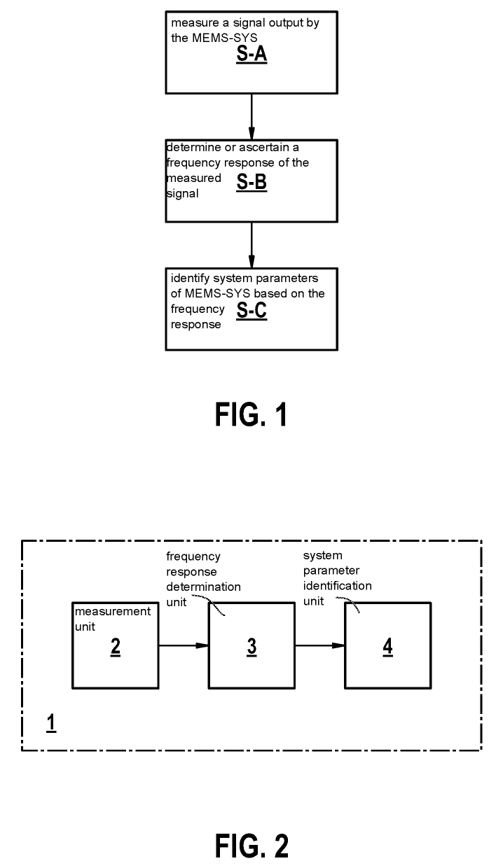

According to a first aspect, the present disclosure provides a method for passively identifying system parameters of a microelectromechanical system MEMS-SYS. An exemplary embodiment of the method is shown schematically in FIG. 1.

In a first step S-A, measuring a signal output by the microelectromechanical system MEMS-SYS excited by noise is carried out. The method according to the present disclosure is based on measuring the unfiltered and uncompensated for signal of the microelectromechanical system MEMS-SYS excited by noise R, for example a microelectromechanical rotation rate sensor.

In a second step S-B, determining or ascertaining a frequency response of the signal measured in step S-A is carried out. In a possible embodiment of the method according to the present disclosure, in step S-B an amplitude frequency response of the measured signal is determined for certain frequencies or frequency ranges.

In one possible embodiment, the measured signal is sampled and filtered. In a possible embodiment, the frequency response of the signal is then determined by fast Fourier transform (FFT) of the filtered signal. By calculating the Fourier transform of the noise signal, the noise signal can be decomposed into the contained frequency components and represented as a transfer function of the system. The frequency split and the quality factor, for example, can be identified from this frequency response.

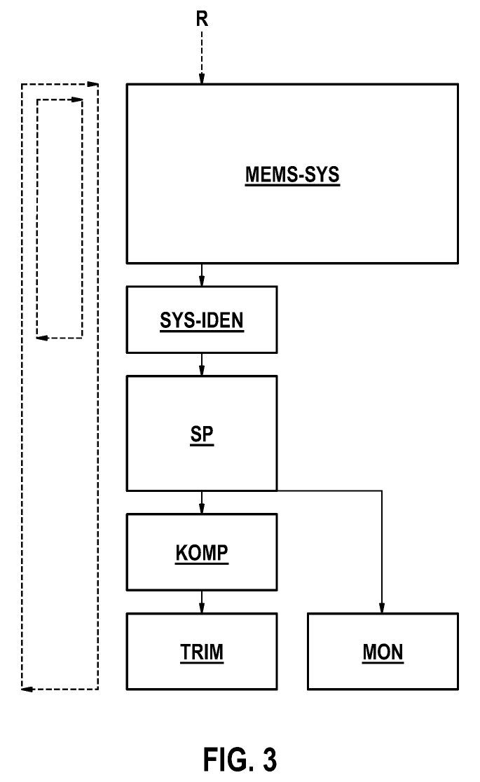

In a further step S-C of the method shown in FIG. 3, identifying system parameters SP of the microelectromechanical system MEMS-SYS is carried out based on the frequency response of the measured signal ascertained in step S-B.

In a possible embodiment of the method according to the present disclosure, the system parameters SP of the microelectromechanical system MEMS-SYS are identified in step S-B based on the frequency response of the measured signal by means of curve fitting, three-point fitting, Kalman filtering or by a correspondingly trained artificial neural network. The identified system parameters SP of the microelectromechanical system MEMS-SYS are subsequently temporarily stored. Curve fitting denotes, in data analysis and statistics, fitting a mathematical function to a set of data points in order to model the relationship between the variables. The goal is to find a function that describes the underlying structure or relationship in the detected data as well as possible.

The method according to the present disclosure makes a passive and continuous system identification possible. Detection of sensor signals does not have to be interrupted for excitation of the system. This makes the adaptation of sensor parameters SP possible during regular sensor operation. The microelectromechanical systems MEMS-SYS adapted by implementation of the method according to the present disclosure, in particular microelectromechanical sensors, follow dynamic changes in the environmental conditions and thus exhibit improved performance.

In addition, the method according to the present disclosure can be used to detect, over time, slow changes within the microelectromechanical system MEMS-SYS or within the environment of the microelectromechanical system MEM-SYS (MON system monitoring) and, if necessary, to trigger further actions. One example of this is the exposure of a sensor to gas. For example, if a crack develops, this leads to a sudden change in pressure in the sensor, which can be easily detected by means of known sensor signals. If the pressure in the sensor changes slowly over time, the quality factor of the sensor also decreases only very slowly. Therefore, detection with known sensor signals is difficult or even impossible when applying conventional methods. The method according to the present disclosure also makes the detection of such slow aging processes possible.

In a possible embodiment of the method according to the present disclosure for passively ascertaining system parameters SP of a microelectromechanical system MEMS-SYS, the microelectromechanical system MEMS-SYS is continuously monitored on the basis of the identified and temporarily stored system parameters SP.

In a possible embodiment of the method according to the present disclosure for passively ascertaining system parameters SP of a microelectromechanical system MEMS-SYS, a compensation mechanism is executed on the basis of the identified and temporarily stored system parameters SP.

In a possible embodiment of the method according to the present disclosure for passively ascertaining system parameters of a microelectromechanical system, the microelectromechanical system MEMS-SYS comprises a microelectromechanical sensor that outputs a signal and whose system parameters SP are identified.

In a possible embodiment of the method according to the present disclosure, the microelectromechanical sensor comprises a rotation rate sensor that outputs a signal and whose system parameters SP are identified.

The method according to the present disclosure is capable, in an efficient manner, of identifying system parameters SP in mode-split MEMS rotation rate sensors (frequency split, quality factor, etc.). Mode-split open-loop MEMS rotation rate sensors are special gyroscopes that are used in microelectromechanical systems (MEMS) for measuring angular velocities. They operate according to the principle of vibration sensor technology and use the Coriolis effect to detect rotation rates.

Mode-split means that the drive mode and the detection mode are at different frequencies, i.e. shifted relative to one another by a frequency split of, e.g. 1 to 6 kHz. A mode-split gyroscope is based on two different oscillation modes of a movable micromechanical resonator. The frequency split denotes the difference between the resonance frequencies of the drive mode and the detection modes. The drive mode is a mechanical oscillation that is excited by external electronics, whereas the detection modes measure the response to a rotation about a certain axis. A rotation rate applied to the system causes, along with the orthogonal primary oscillation (drive mode), a Coriolis force that leads to deflection of the secondary oscillation (detection mode). This deflection is detected. In a MEMS rotation rate sensor (gyroscope), the drive mode and the detection mode play a central role. These two terms describe the oscillation states of the mechanical system that are used for measuring the angular velocity. The drive mode denotes the mechanical oscillation that is actively generated in the sensor in order to make measuring the rotation rate possible. An actuator, often electro- or piezoelectric, causes a mass in the sensor to oscillate in a controlled manner. This oscillation is preferably carried out at the natural frequency of the system in order to maximize energy efficiency. The oscillation takes place in a certain direction or plane. The oscillation generates an output signal that is influenced by a rotational motion. The drive mode represents the primary mechanical motion by which the Coriolis force can be measured. The detection mode is the mechanical oscillation or displacement that arises as a response to the rotational motion and is measured. When the sensor is in rotation, the Coriolis force acts perpendicular to the drive direction. This force causes the mass to oscillate along a second, orthogonal direction. The motion of the detection mode is typically orthogonal to the motion of the drive mode. The amplitude or frequency of the detected oscillation is proportional to the angular velocity. This motion is measured by capacitive or piezoelectric elements.

In a possible embodiment of the method according to the present disclosure for passively ascertaining system parameters SP of a microelectromechanical system MEMS-SYS, the system parameters SP of the rotation rate sensor comprise a frequency split of the rotation rate sensor and/or a quality factor of the rotation rate sensor.

The quality factor of a rotation rate sensor (gyroscope) is a measure of the efficiency with which the mechanical system retains energy in its oscillations. It is often referred to as the Q-factor (quality factor) and decisively influences the performance of the sensor. The quality factor is defined as the ratio of stored energy to the energy lost per oscillation period.

A high Q-factor means that the sensor loses little energy due to internal or external losses and is therefore more sensitive. A higher quality factor results in stronger amplification of the Coriolis force and thus better detection of small rotational motions. A high Q-factor reduces the influence of noise and increases signal stability, in particular in systems without feedback (open-loop).

The most important system parameters SP in mode-split rotation rate sensors comprise, along with frequency split and quality factor, the natural frequencies, Coriolis sensitivity, mode stiffness and damping losses. An optimal design aims to achieve a high quality factor and sensitivity, along with reducing noise and temperature dependencies.

As schematically shown in FIG. 2, according to a second aspect, the present disclosure further provides a device 1 for passively identifying system parameters SP of a microelectromechanical system MEMS-SYS comprising a measurement unit 2, which is configured to measure a signal output by the microelectromechanical system MEMS-SYS excited by noise R. The device 1 further comprises a frequency response determination unit 3 which is configured to determine a frequency response of the signal measured by the measurement unit 2. The device 1 additionally comprises a system parameter identification unit 4, which is configured to identify system parameters SP of the microelectromechanical system MEMS-SYS based on the frequency response of the measured signal determined by the frequency response determination unit 3.

According to a further aspect, the present disclosure further provides a micromechanical system MEMS-SYS comprising a device 1 integrated therein or connected thereto for passively identifying system parameters of the microelectromechanical system MEMS-SYS according to the second aspect of the present disclosure. In a possible embodiment of the microelectromechanical system, the microelectromechanical system MEMS-SYS comprises a rotation rate sensor. In a possible embodiment of the microelectromechanical system, the microelectromechanical system MEMS-SYS comprises an acceleration sensor.

In a possible embodiment, the microelectromechanical system MEMS-SYS comprises at least one microelectromechanical sensor, in particular a rotation rate sensor, which is monitored with the aid of the method according to the present disclosure and a device 1 according to the present disclosure connected to said sensor.

The uncompensated for and unfiltered detection signal of the microelectromechanical system MEMS-SYS (using a rotation rate sensor as an example) is initially sampled and provided at a sufficiently high sampling rate. The sampling rate is sufficient to satisfy the Nyquist-Shannon sampling theorem.

In the method according to the present disclosure, the microelectromechanical system MEMS-SYS is not excited via dedicated electrodes; rather, the existing excitation of the microelectromechanical system MEMS-SYS by noise R is utilized.

In a first step S-A of the method according to the present disclosure, measuring a signal output by the microelectromechanical system MEMS-SYS excited by noise R is carried out. It is important that the sum of the noise sources always represents a sufficiently large excitation of the microelectromechanical system MEMS-SYS. Possible noise sources comprise, for example, Brownian noise along with the noise of the applied electrical voltages.

FIG. 3 schematically shows applying a noise signal R to a MEMS system (e.g. a rotation rate sensor) that comprises a transfer function H. The MEMS system delivers a time signal SIG. After sampling, filtering and transforming the time signal SIG into a spectrum or a frequency response, system parameters SP of the MEMS system can be identified by a system parameter identification SP-IDENT. These system parameters SP comprise, for example, frequencies, quality factors, phases, gains, mechanical parameters or manufacturing parameters. Subsequently, based on the ascertained system parameters SP, an algorithm for calculating a compensation specification KOMP and/or for adapting an operating state of the microelectromechanical system MEMS-SYS can be executed. A trimming TRIM for compensating for environmental influences and/or aging processes of the microelectromechanical system MEMS-SYS can then be executed. This is preferably executed continuously during ongoing operation of the microelectromechanical system MEMS-SYS. Alternatively or additionally, system monitoring SYS-MON of the microelectromechanical system MEMS-SYS can be carried out, which can likewise be executed in the background during ongoing operation of the microelectromechanical system MEMS-SYS, as shown in FIG. 3.

In order to execute a system parameter identification SP-IDENT based on the noise signal R, in a possible embodiment in step S-B of the method according to the present disclosure, the amplitude frequency response is calculated, at least for dedicated frequencies or frequency ranges, with the aid of a Fourier transform (e.g. an FFT). The sampled signal can be filtered before the Fourier transform.

Based on the frequency response ascertained in step S-B, system parameter identification SP-IDENT is then executed in a third step S-C, in order to determine, for example, the frequency split of the detection mode. The frequency split can be identified at the location of a resonance frequency in the frequency response. A possible implementation can also comprise averaging a plurality of frequency responses calculated consecutively, for example.

The additionally superimposed loop, as indicated in the flow chart according to FIG. 3, can also be operated with a higher repetition rate. For subsequently identifying the system parameters SP, application of methods such as curve fitting, three-point fitting, or application of Kalman filters and artificial neural networks, inter alia, are possible.

The system parameters SP determined thereby can, on the one hand, be used for the continuous online system monitoring of the microelectromechanical system MEMS-SYS. On the other hand, the data can be used in a downstream algorithm for adapting the calculation specifications of the compensation mechanisms or for adapting the operating state. Possible compensation mechanisms can be applied directly to the corresponding measured variables or directly to the microelectromechanical system MEMS-SYS, for example a sensor system. An example of a direct application is, for example, the continuous adjustment of the stop frequency band of notch filters used in the signal path of a MEMS rotation rate sensor.

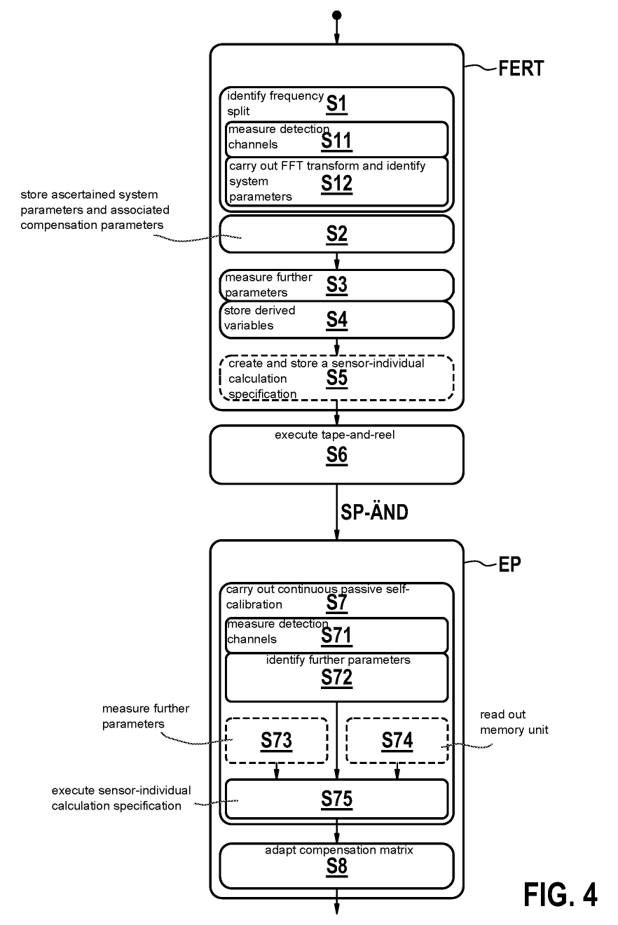

In FIG. 4, the method according to the present disclosure is used to implement efficient measuring of the frequency split, first in manufacturing and then continuously in the field. Continuous self-calibration in the field improves performance by compensating for, for example, temperature, humidity and mechanical stress effects.

During the manufacturing and/or production FERT of the microelectromechanical system MEMS-SYS, a frequency split of the MEMS sensor can be identified in a step S1, without active excitation of the microelectromechanical system MEMS-SYS. This is executed in a first sub-step S11 by measuring detection channels of the MEMS sensor, for example of a gyroscope. Subsequently, during manufacturing FERT of the microelectromechanical system MEMS-SYS, in a further sub-step S12, an FFT transform of the time signal SIG and an identification of system parameters SP, such as frequency or quality factor, is carried out. The ascertained system parameters SP and associated compensation parameters KP can be stored in a memory unit in a step S2. Further parameters can be measured in step S3. These parameters can be stored in a memory unit of the manufactured microelectromechanical system MEMS-SYS in a step S4. In addition, in step S4, derived variables can be stored in the memory unit of the manufactured microelectromechanical system MEMS-SYS.

Optionally, in a step S5 during manufacturing, a sensor-individual calculation specification can be created and stored in a memory unit of the manufactured microelectromechanical system MEMS-SYS. Further manufacturing steps such as tape-and-reel can be executed in a further step S6. The manufactured microelectromechanical system MEMS-SYS is transported and can be soldered onto an end product EP. Subsequently, in step S6, if applicable, conditioning and adaptation to environmental changes, mechanical shocks and aging processes are carried out.

If the frequency split or another system parameter SP changes SP-ÄND, the system parameters SP and the associated compensation parameters KP no longer match exactly. Therefore, in the delivered end product EP located in the field, which end product contains the microelectromechanical system MEMS-SYS, in step S7, a continuous passive self-calibration of the microelectromechanical system MEMS-SYS can be carried out. For this purpose, in a first sub-step S71, the detection channels of the microelectromechanical system MEMS-SYS, in particular of a MEMS rotation rate sensor, are measured. Furthermore, in a sub-step S72, further parameters in all three axes of the MEMS rotation rate sensor can be identified based on the resulting system response. If applicable, measuring further parameters is carried out in a sub-step S73 and/or, if applicable, in a sub-step S74, the reading out of a memory unit of the microelectromechanical system MEMS-SYS is carried out. Then, in a sub-step S75 of the self-calibration S7, execution of the sensor-individual calculation specification created in step S5 for the MEMS sensor is carried out. In a step S8, an adaptation of the compensation matrix can follow. Via the method according to the present disclosure, a significant improvement of the performance of the microelectromechanical system MEMS-SYS can be achieved.

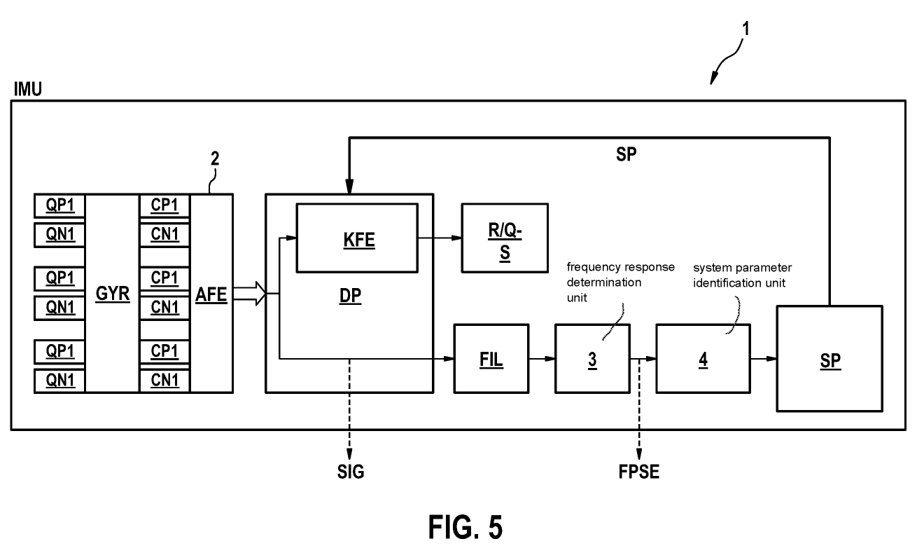

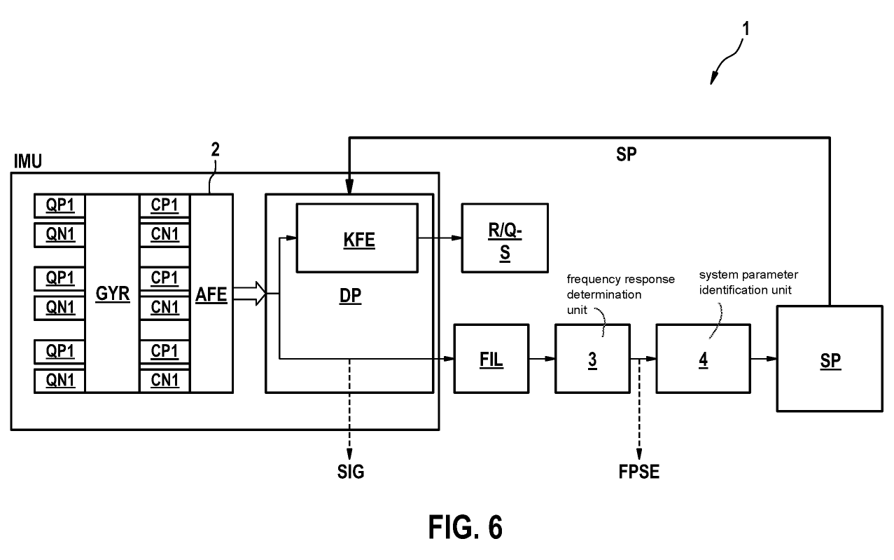

In FIG. 5 and FIG. 6, possible implementation options of the approach according to the present disclosure are shown, namely an implementation either directly in a MEMS sensor (as shown in FIG. 5) or in an external signal processing connected thereto (as shown in FIG. 6).

FIG. 5 and FIG. 6 show an inertial measurement unit IMU as an example of a microelectromechanical system MEMS-SYS. A gyroscopic unit GYR is connected, via an analog front end AFE, to a digital processor DP of the inertial measurement unit IMU. The analog front end AFE in the MEMS gyroscopic sensor is a circuit component that processes the analog signals of the sensor and prepares them for further digital processing. The analog front end AFE, as measurement unit 2, can measure and amplify the electrical signals coming from the MEMS structures in order to make them evaluable. The analog front end AFE can analog-filter the received high-frequency sensor signal in order to increase the signal quality of the measured sensor signal. Furthermore, the analog front end AFE can comprise an analog-to-digital converter ADC that samples the analog signals at a sampling rate and supplies the sampled signal to the digital processor DP of the inertial measurement unit IMU for data processing. The digital processor DP delivers a digital time signal SIG, which is filtered by a filter unit FIL. The filtered time signal is converted, by a transformation unit 3, into a digital frequency spectrum FSPE that reproduces the frequency response of the MEMS sensor, as shown in FIG. 5 and FIG. 6.

As shown in FIG. 5 and FIG. 6, in a possible embodiment, a filter unit FIL for filtering the digitized sensor signal SIG is provided. An FFT unit 3 executes an FFT transform in the shown embodiment and delivers a frequency spectrum FSPE of the sensor signal SIG. An identification unit 4 executes curve fitting for ascertaining the system parameters SP. These system parameters SP comprise, for example, a frequency split and a quality factor Q of the sensor for certain frequency ranges and/or frequency channels CH. The ascertained system parameters SP can be supplied to a compensation and filter unit KFE of the digital processor DP, in order to a execute passive, continuous monitoring of the MEMS system based on the ascertained system parameters SP. In the shown exemplary embodiment, the compensation and filter unit KFE of the digital processor DP delivers a rate/quad signal R/Q-SI, as shown in FIG. 5 and FIG. 6. Along with use of the passive continuous method according to the present disclosure for passively identifying system parameters SP of a micromechanical system MEMS-SYS, combination with an active method is additionally possible.

The method according to the present disclosure comprises a passive, continuous method for system identification (e.g. measuring the frequency split) in MEMS systems, in particular in MEMS rotation rate sensors. This method can comprise a continuous self-test and/or a continuous self-calibration, without the use of active excitation being necessary. When executing measurements under different sensor conditions, a MEMS sensor can dynamically adapt with the aid of the method according to the present disclosure.

The method according to the present disclosure is suitable for different MEMS systems, in particular in the automotive, consumer and industrial fields, for example for rotation rate sensors and acceleration sensors. The method according to the present disclosure can also be applied to other resonant sensor systems.

Although the present invention has been completely described above with reference to preferred exemplary embodiments, it is not limited thereto, but can be modified in many ways.

What is claimed is:

1. A method for passively identifying system parameters of a microelectromechanical system, the method comprising the following steps:
measuring a signal output by the microelectromechanical system excited by noise;
determining a frequency response of the measured signal; and
identifying system parameters of the microelectromechanical system based on the frequency response of the measured signal.

2. The method according to claim 1, wherein an amplitude frequency response of the measured signal is determined for certain frequencies or frequency ranges.

3. The method according to claim 1, wherein the measured signal is sampled and filtered, and the frequency response of the signal is determined, by a frequency response determination unit, using a fast Fourier transform (FFT) of the filtered signal.

4. The method according to claim 1, wherein the system parameters of the microelectromechanical system are identified, by an identification unit, based on the frequency response of the measured signal, using: curve fitting, or three-point fitting, or Kalman filtering, or by an artificial neural network.

5. The method according to claim 1, wherein the identified system parameters of the microelectromechanical system are stored.

6. The method according to claim 1, wherein the microelectromechanical system is continuously monitored based on the identified system parameters.

7. The method according to claim 1, wherein a compensation mechanism is executed based on the identified system parameters of the microelectromechanical system.

8. The method according to claim 1, wherein the microelectromechanical system includes a microelectromechanical sensor that outputs the signal, and wherein the identified system parameters are parameters of the microelectromechanical sensor.

9. The method according to claim 8, wherein the microelectromechanical sensor includes a rotation rate sensor that outputs the signal, and wherein the identified system parameters are parameters of the rotation rate signal.

10. The method according to claim 9, wherein the system parameters of the rotation rate sensor include a frequency split of the rotation rate sensor and a quality factor of the rotation rate sensor.

11. A device for passively identifying system parameters of a microelectromechanical system, the device comprising:
a measurement unit configured to measure a signal output by the microelectromechanical system excited by noise;
a frequency response determination unit configured to determine a frequency response of the signal measured by the measurement unit; and
a system parameter identification unit configured to identify system parameters of the micromechanical system based on the frequency response of the measured signal determined by the frequency response determination unit.

12. A microelectromechanical system, comprising:
a device configured to passively identify system parameters of the microelectromechanical system, the device comprising:
a measurement unit configured to measure a signal output by the microelectromechanical system excited by noise,
a frequency response determination unit configured to determine a frequency response of the signal measured by the measurement unit, and
a system parameter identification unit configured to identify system parameters of the micromechanical system based on the frequency response of the measured signal determined by the frequency response determination unit.

13. The microelemechanical system according to claim 12, wherein the microelectromechanical system includes a rotation rate sensor or an acceleration sensor.
